(19) United States
(12) Patent Application Publication
(10) Pub. No.: US 2012/0108072 A1
(43) Pub. Date: May 3, 2012

(54) SHOWERHEAD CONFIGURATIONS FOR PLASMA REACTORS

(76) Inventors: Ivelin A. Angelov, Sunnyvale, CA (US); James E. Caron, Tracy, CA (US); Ilia Kalinovski, Berkeley, CA (US); Zhao Li, Sunnyvale, CA (US)

(21) Appl. No.: 12/916,269

(22) Filed: Oct. 29, 2010

(51) Int. Cl. H01L 21/3065; G03B 27/42; B05B 1/14; H01L 21/02; C23F 1/08

(52) U.S. Cl. 438/712; 156/345.34; 239/548; 355/53; 257/E21.218

(57) ABSTRACT

Apparatus, devices, and methods for increasing the ion energy in a plasma processing devices are provided. In various embodiments, the surface area of a showerhead facing the work piece includes a plurality of features. The plurality of features increases the surface area of the showerhead relative to a flat surface. Increasing the surface area of the showerhead increases the ion energy without increasing the power used to generate the plasma. Increasing the ion energy using such a showerhead allows for the broader application of plasma processes in integrated circuit manufacturing.

### BACKGROUND

Damascene processing techniques are used in many modern integrated circuit manufacturing schemes because these techniques require fewer processing steps and offer a higher yield than other methods. Damascene processing involves forming metal conductors on integrated circuits by forming inlaid metal lines in trenches and vias in a dielectric layer (inter-metal dielectric). As part of the Damascene process, a layer of photoresist is deposited on a dielectric layer. The photoresist is a light-sensitive organic polymer which can be “spun on” in liquid form and dries to a solid thin film. The photosensitive photoresist is then patterned using light through the mask and wet solvent. A plasma etching process (i.e., dry etch) is then used to etch exposed portions of dielectric and transfer the pattern into the dielectric, forming vias and trenches in the dielectric layer.

Once the dielectric layer is etched, the photoresist is stripped and any etch-related residues are removed before subsequent processing to avoid embedding impurities in the device. Conventional processes for stripping photoresist employ a plasma formed from a mixture of gases with the presence of oxygen in the plasma. The highly reactive oxygen-based plasma reacts with and oxidizes the organic photoresist to form volatile components that are carried away from the wafer surface.

### SUMMARY

Provided herein are showerheads for use in plasma processing devices. According to various embodiments, the showerhead includes surface features that increase the surface area of the showerhead relative to a flat surface. Increasing the surface area of the showerhead relative to a flat surface in this manner allows the ion energy of the plasma to be increased without increasing the showerhead and/or processing chamber dimensions. The plasma processing devices are used for removing material from the surface of a work piece, for example. Also provided are methods for removing material from the surface of a work piece. One aspect relates to a plasma processing device. The plasma processing device includes a work piece support and a showerhead. The work piece support is configured to support a work piece. The showerhead includes a plurality of holes configured to allow gaseous species to pass into a region between the work piece support and the showerhead. A surface of the showerhead facing the work piece support includes a plurality of features configured to increase the surface area of the showerhead relative to a flat surface.

In certain embodiments the plurality of features includes concentric ridges and concentric valleys. In various embodiments the plurality of features includes: ridges and valleys radiating from a center of the showerhead; ridges and valleys running across the showerhead; a plurality of periodically arrayed features; or a plurality of randomly patterned features.

In further embodiments the plasma processing device includes a plasma source chamber. The plasma source chamber is located upstream from the showerhead and the gaseous species allowed to pass through the showerhead includes radicals from the plasma source chamber.

In certain embodiments the device also includes an RF power source configured to apply radio frequency power to the work piece support. The radio frequency power source includes a low frequency power source in some cases and a a high frequency power source in other cases.

In certain embodiments the plurality of holes in the showerhead includes about 24,000 holes. In some embodiments the showerhead comprises an aluminum alloy. The distance between the surface of the showerhead and the work piece support is about 0.1 to 0.9 inches in some embodiments, and about 1.2 inches in other embodiments.

Another aspect relates to an apparatus configured for semiconductor lithography. The apparatus includes a device configured for photoresist application, a device configured for photoresist exposure, and a device as described above configured for photoresist removal.

Another aspect relates to a showerhead configured to use in a plasma processing device. The showerhead includes a plurality of holes configured to allow gaseous species to pass and a surface configured to face a work piece. The surface includes a plurality of features configured to increase the surface area of the showerhead relative to a flat surface.

In certain embodiments the plurality of features includes concentric ridges and concentric valleys. In various embodiments, the plurality of features includes: ridges and valleys radiating from a center of the showerhead; ridges and valleys running across the showerhead; a plurality of periodically arrayed features; or a plurality of randomly patterned features. In some embodiments the plurality of holes in the showerhead includes about 24,000 holes. In some embodiments the showerhead is an aluminum alloy.

Another aspect relates to a method. The method includes all or some of the following: introducing a gas into a processing chamber through a plurality of holes in a showerhead; generating a plasma between the showerhead and a work piece support, a surface of the showerhead facing the work piece support including a plurality of features configured such that a plasma sheath of the plasma follows a contour of the features, the work piece support configured to support a work piece; and impinging ions from the plasma on a surface of the work piece to remove a material from the surface of the work piece. In some embodiments the plurality of features is configured such that arcing between features of the plurality of features is prevented. In some embodiments the plasma sheath of the plasma following a contour of the features on the surface of the showerhead increases the effective surface area of the showerhead.

In certain embodiments the material that is removed includes a photoresist, the photoresist overlaying a low-K dielectric. The material may include a polyimide.

In certain embodiments generating the plasma includes applying a radio frequency power to the work piece support. In some cases, the radio frequency power includes a high frequency power at about 13.56 mega-Hertz or at about 27 mega-Hertz. In other cases, the radio frequency power includes a low frequency power at about 1 mega-Hertz or at about 400 kilo-Hertz.

In certain embodiments impinging the ions on the surface of the work piece includes impinging the ions with sufficient kinetic energy to remove the material with the work piece at a temperature of about 20 to 25° C. The gas is introduced into the processing chamber through a plurality of holes in the showerhead includes radicals generated from an inductively coupled plasma, in some embodiments. The gas may include oxygen radicals. The pressure of the gas in the processing chamber is about 25 milli-torr to 100 ton in some embodiments.

Another related method includes generating a plasma from a gaseous species in a processing chamber and impinging ions from the plasma on a surface of the work piece to remove a material from the surface of the work piece. The processing chamber includes a work piece support, the work piece support configured to support a work piece; and a showerhead, the showerhead including a plurality of holes configured to allow the gaseous species to pass into a region between the work piece support and the showerhead, and a surface of the showerhead facing the work piece support including a plurality of features configured to increase the surface area of the showerhead relative to a flat surface.

These and other aspects of the invention are described further below with reference to the figures.

### BRIEF DESCRIPTION OF THE DRAWINGS

The accompanying drawings, which are incorporated in and form part of the specification, illustrate embodiments of the invention and, together with the detailed description, serve to explain the embodiments of the invention:

FIG. 1A is a schematic diagram of a downstream plasma device according to certain embodiments.

FIG. 1B is a schematic diagram of a capacitively coupled plasma device according to certain embodiments.

FIG. 2 is a graph showing the ion flux (the number of ions through a unit area per unit time in a plasma) versus ion energy for a plasma generated with a HF (13.6 MHz) RF power and a plasma generated with a LF (100 kHz) RF power.

FIG. 3 depicts an embodiment of a showerhead.

FIGS. 4A-4C depict further embodiments of showerheads.

FIG. 5 includes a schematic diagram of a capacitively coupled plasma device including a plasma with a plasma sheath and a graph showing the calculated thickness of the sheath versus pressure in a processing chamber for a set of operating conditions.

FIG. 6 is a schematic diagram of a stripping tool according to certain embodiments.

FIG. 7 depicts a process flow diagram according to certain embodiments.

FIG. 8 is a graph showing thermal oxide removal rate versus the plasma power using a capacitively coupled plasma device outfitted with different showerheads.

### DETAILED DESCRIPTION

In the following detailed description of the present invention, numerous specific embodiments are set forth in order to provide a thorough understanding of the invention. However, as will be apparent to those skilled in the art, the present invention may be practiced without these specific details or by using alternate elements or processes. In other instances well-known processes, procedures and components have not been described in detail so as not to unnecessarily obscure aspects of the present invention.

In this application, the terms “semiconductor wafer,” “wafer,” and “partially fabricated integrated circuit” are used interchangeably. One skilled in the art would understand that the term “partially fabricated integrated circuit” can refer to a silicon wafer during any of many stages of integrated circuit fabrication thereon. The following detailed description assumes the invention is implemented on a wafer. However, the invention is not so limited. The work piece may be of various shapes, sizes, and materials. In addition to semiconductor wafers, other work pieces that may take advantage of this invention include various articles such as printed circuit boards and the like.

Plasma reactor chamber apparatus used for integrated circuit manufacturing include apparatus configured to remove photoresist materials and other residue materials from a partially fabricated integrated circuit. Examples of such apparatus include the Gamma 2100, 2130 I²CP (Interlaced Inductively Coupled Plasma), G400, GxT, and the SIERRA, offered by Novellus Systems, Inc. of San Jose, Calif. Other systems include the Fusion line from Axcelis Technologies Inc. of Rockville, Md., TERA21 from PSK Tech Inc. in Korea, and the Aspen from Mattson Technology Inc. in Fremont, Calif. Additionally, various plasma reaction chambers may be associated with cluster tools. For example, a strip chamber may be added to a Centura cluster tool available from Applied Materials of Santa Clara, Calif.

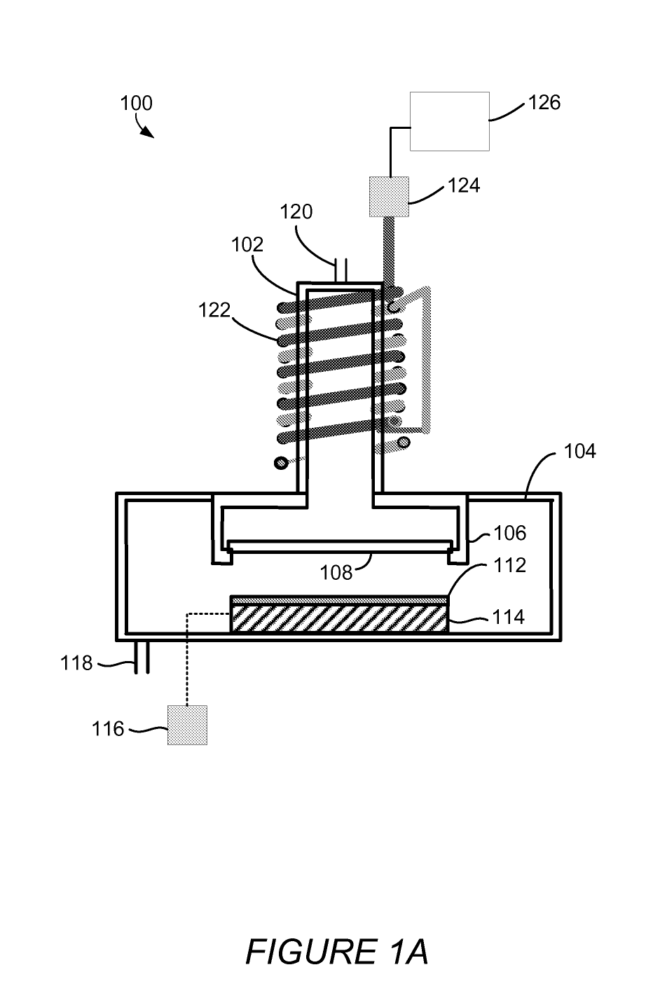

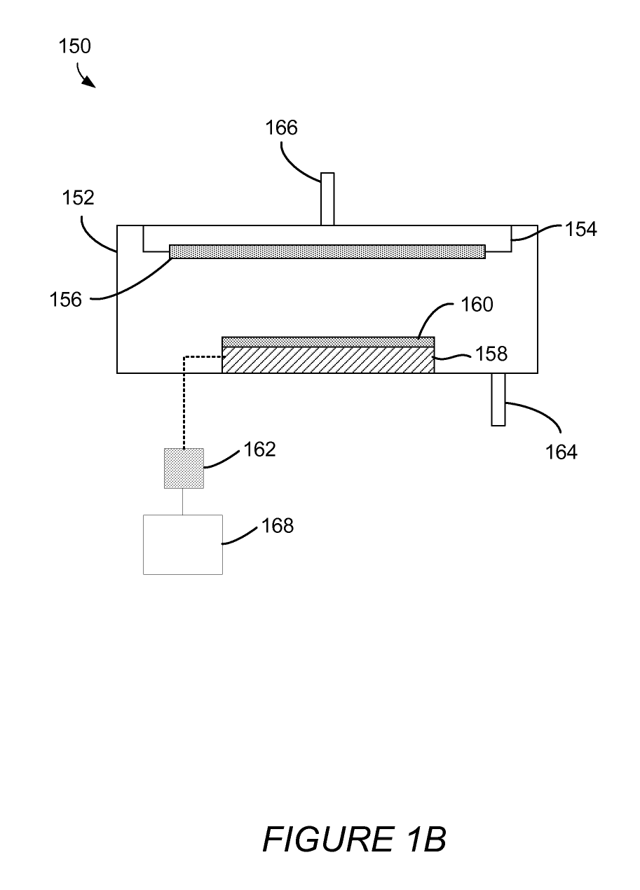

FIG. 1 is a schematic illustration of a downstream plasma device 100 according to certain embodiments. The device 100 has a downstream plasma source chamber 102 and an exposure chamber 104 separated by a showerhead assembly 106.

The showerhead assembly 106 includes a showerhead 108. Inside the exposure chamber 104, a wafer 112 rests on a platen, stage, or work piece support 114. In some embodiments the surface of the showerhead 108 facing the platen 114 is about 0.5 to 2 inches from the surface of a wafer on the platen 114. In further embodiments the surface of the showerhead 108 facing the platen 114 is about 1.2 inches from the surface of a wafer on the platen 114. In yet further embodiments the surface of the showerhead 108 facing the platen 114 is about 0.1 to 0.9 inches from the surface of a wafer on the platen. The thicknesses of wafers is generally less than about 1 mm, so the distance between the surface of the showerhead and the surface of a wafer can generally be considered the distance between the surface of the showerhead and the platen when the wafer rests directly on the platen. In cases where the wafer rests on a support structure (e.g., lift pins or a gas flow blanket) on the platen, the distance between the surface of the showerhead and the surface of a wafer can generally be considered the distance between the surface of the showerhead and the support structure.

In some embodiments the platen 114 is fitted with a heating/cooling element. A radio frequency (RF) power source 116 is configured to apply RF power to the platen 114. The RF power source 116 is a low frequency (LF) power source in some embodiments, and the RF power source 116 is a high frequency (HF) power source in other embodiments. For example, the low frequency power source has a frequency of about 50 kilo-Hertz (kHz) to 1 mega-Hertz (MHz) and the high frequency power source has a frequency of about 2 to 200 mega-Hertz (MHz), in some embodiments. In other embodiments the low frequency power source has a frequency of about 400 kHz and the high frequency power source has a frequency of about 13.56 MHz. In further embodiments the RF power source includes both a LF and a HF power source.

Low pressure is attained in the exposure chamber 104 via a vacuum pump (not shown) via a conduit 118. Gas sources (not shown) provide a flow of process gas via an inlet 120 into the plasma source chamber 102 of the device 100. The plasma source chamber 102 is surrounded in part by induction coils 122, which are in turn connected to a power source 124. Various configurations and geometries of the plasma source chamber 102 and the induction coils 122 may be used. For example, the induction coils 122 may loop around the plasma source chamber 102 in an interlaced pattern. In another example, the plasma source chamber 120 may be shaped as a dome instead of a cylinder. A controller 126 may be connected to components of the device 100 to control the operation of device 100. For example, the controller 126 may be connected to the power supply 124. The controller 126 may also be connected to other components of the device 100 to control, for example, the process gas composition and pressure, and the temperature of the platen 114. Machine-readable media may be coupled to the controller 124 and contain instructions for controlling process conditions for the operations in the device 100.

During operation, gas mixtures are introduced into the plasma source chamber 102 and the induction coils 122 are energized with power source 124 to generate a plasma (i.e., the induction coils generate an inductively coupled plasma in the plasma source chamber 102). The showerhead 108 includes a plurality of holes or passageways (not shown) though which plasma species from the plasma may pass and enter the exposure chamber 104. The showerhead 108, with a voltage applied to it, in some embodiments, terminates the flow of ions from the plasma and allows the flow of radicals and other neutral species from the plasma into the exposure chamber 104.

RF power is then applied with the RF power source 116 to the platen 114. This RF power creates additional ions from the radicals and other neutral species from the plasma that pass through the showerhead 108 (i.e., the RF power source 116 generates a capacitively coupled plasma). The pressure in the exposure chamber is about 300 milli-torr (mtorr) to 1.5 torr in some embodiments, and about 5 mtorr to over 200 mtorr in further embodiments. A DC bias voltage is created between the showerhead 108 and the work piece 112 due to the RF power applied to the platen 114. This DC bias accelerates ions towards the platen where the ions impinge the wafer 112 or other work piece on the platen. Ions impinging the wafer result in isotropic sputtering and/or ion-assisted chemical reactions between the ions and materials on the wafer, depending on the reactivity and energy of the ions in the plasma. A feature of such a downstream plasma device 100 is that the power applied to plasma source chamber 102 is decoupled from the bias power of the platen. This decoupling of the power allows for greater control over the ion density and the ion energy.

In some embodiments the RF power source 116 generates the plasma in the exposure chamber 104 using HF RF power only. Ions do not follow or “ride” the HF RF field, meaning that the ions are not accelerated through the plasma sheath (described below) during one half-cycle of the HF RF power.

In other embodiments the RF power source 116 generates the plasma in the exposure chamber 104 using both HF and LF RF power or using LF RF power only. Ions do follow or “ride” the LF RF field to a certain extent, which results in a wider distribution of ion energies and may result in wafer damage or sputtering of the showerhead 108.

FIG. 1B is a schematic diagram of a capacitively coupled plasma device according to certain embodiments. The device 150 is similar to the downstream plasma device 100, with the device 150 not having a downstream plasma source chamber. The device 150 includes a processing chamber 152 with a showerhead assembly 154. The showerhead assembly includes a showerhead 156. Inside the processing chamber 154, a wafer 160 rests on a platen, stage, or work piece support 158. The spacing between the surface of the showerhead 156 and the wafer or work piece on the platen 158 is as described above. In some embodiments the platen 158 is fitted with a heating/cooling element. A radio frequency (RF) power source 162 is configured to apply RF power to the platen 158. The RF power source 162 is a low frequency (LF) power source in some embodiments, and the RF power source 162 is a high frequency (HF) power source in other embodiments. For example, the low frequency power source has a frequency of about 50 kilo-Hertz (kHz) to 1 mega-Hertz (MHz) and the high frequency power source has a frequency of about 2 to 200 mega-Hertz (MHz), in some embodiments. In other embodiments the low frequency power source has a frequency of about 1 mega-Hertz (MHz) and the high frequency power source has a frequency of about 27 mega-Hertz (MHz). In further embodiments the low frequency power source has a frequency of about 400 kilo-Hertz (kHz) and the high frequency power source has a frequency of about 13.56 mega-Hertz (MHz). In yet further embodiments the RF power source includes both a LF and a HF power source. This dual frequency configuration is typically configured to provide a more independent control of the ion density and ion energy. This is possible because the plasma density typically scales as the frequency squared. A controller 168 may be connected to components of the device 150 to control the operation of the device 150. For example, the controller 168 may be connected to the power supply 162. The controller 162 may also be connected to other components of the device 150 to control, for example, the temperature of the platen 158. Machine-readable media may be coupled to the controller 168 and contain instructions for controlling process conditions for the operations in the device 150. Low pressure is attained in the processing chamber 152 via a vacuum pump (not shown) via a conduit 164.

During operation, gasses or gas mixtures are introduced into the processing chamber 152 from gas sources (not shown) via an inlet 166 and a plurality of holes or passageways (not shown) in the showerhead 156. The pressure in the processing chamber is about 5 milli-torr (mtorr) to 100 ton in some embodiments, and about 600 mtorr in further embodiments. In other embodiments the pressure in the processing chamber is about 25 mtorr to 200 torr. RF power is then applied with the RF power source 162 to the platen 158. This RF power creates ions from the gas or gas mixture in the processing chamber 152. The ions impinge on the wafer surface and sputter and/or chemically react with materials on the wafer surface.

In further embodiments gasses are introduced to the processing chamber of a capacitively coupled plasma device from the side or other inlet and not though the showerhead. In these embodiments, a plate (i.e., a showerhead without the holes or passageways) or other surface is used instead of a showerhead.

The gasses introduced into the devices described above vary with the application. In some embodiments the gasses include oxygen and or oxygen and nitrogen. Ionized oxygen in oxygen-based plasmas reacts with organic materials on the surface of a wafer, including photoresist or other polymeric material, and “ashes” or “burns” the material. In other embodiments the gasses include a fluorinated species, such as carbon tetrafluoride or nitrogen trifluoride. In further embodiments the gasses include argon. In embodiments where chemically reactive ions are formed in the plasma, the kinetic energy of the ions may supply some of the activation energy needed for the chemical reaction, as described below. In embodiments where only an inert gas (e.g., argon) is used to form the plasma, the ions physically sputter the material on the surface of the wafer.

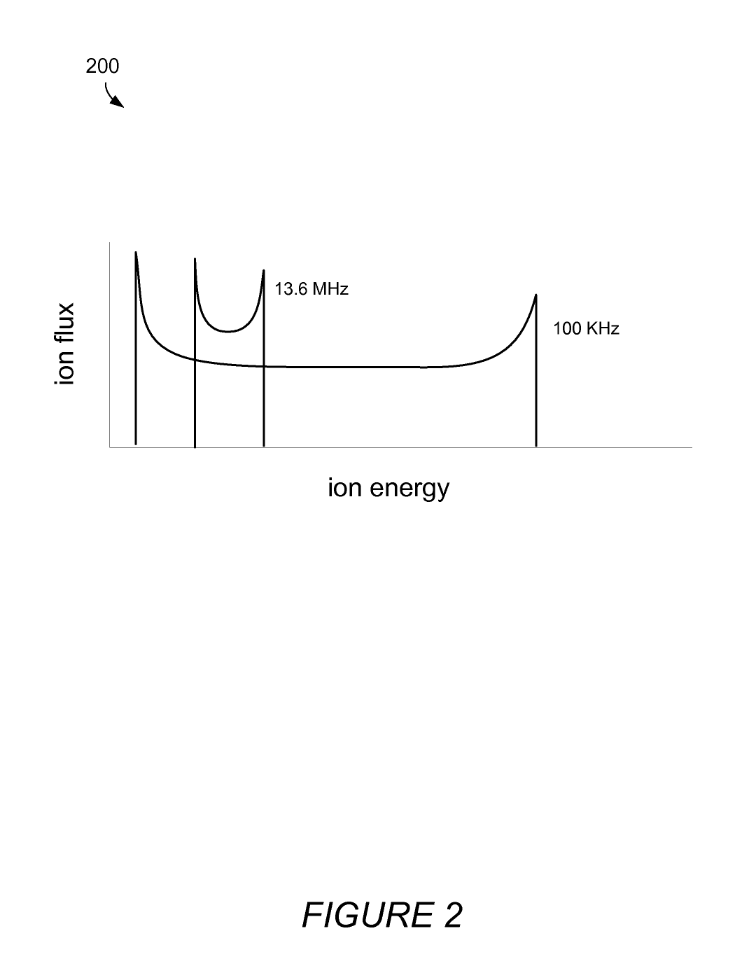

FIG. 2 is a graph 200 showing the ion flux (the number of ions through a unit area per unit time in a plasma) versus ion energy for a plasma generated with a HF (13.6 MHz) RF power and a plasma generated with a LF (100 kHz) RF power. In a plasma processing operation, the ion energy provides the energy needed to sputter a material on a work piece surface and/or the activation energy needed for a chemical reaction. The wide distribution of ion energies and higher ion energies generated with the LF RF power is useful for applications in some embodiments. The narrow distribution of ion energies generated with the HF RF power is useful for applications in other embodiments. For example, it may be necessary to use LF RF generated plasma in some applications to achieve an ion energy sufficient to react with and/or sputter material from a wafer. The LF RF generated plasma, however, may damage the surface or underlying features in the wafer.

The ion energy is directly affected by the bias between the showerhead and the platen. This bias, in turn, is partially governed by the area of the surface of the showerhead (or grounded electrode) and the area of the surface of the platen (or powered electrode). The equation governing the bias voltage is given in equation 1.

$$\frac{{V}_{power}}{{V}_{ground}} = {( \frac{{A}_{ground}}{{A}_{power}} )}^{\frac{5}{2}} \qquad Equation 1$$

V_{power} is the sheath voltage on the powered electrode, V_{ground} is the sheath voltage on the grounded electrode, A_{ground} in the surface area of the grounded electrode, and A_{power} is the surface area of the powered electrode. In the downstream plasma device 100 and the capacitively coupled plasma device 150, the showerhead is the grounded electrode and the platen is the powered electrode. According to Equation 1, the larger the difference in the surface area of the grounded electrode compared to the surface area of the powered electrode, the higher the bias between the grounded electrode and the powered electrode.

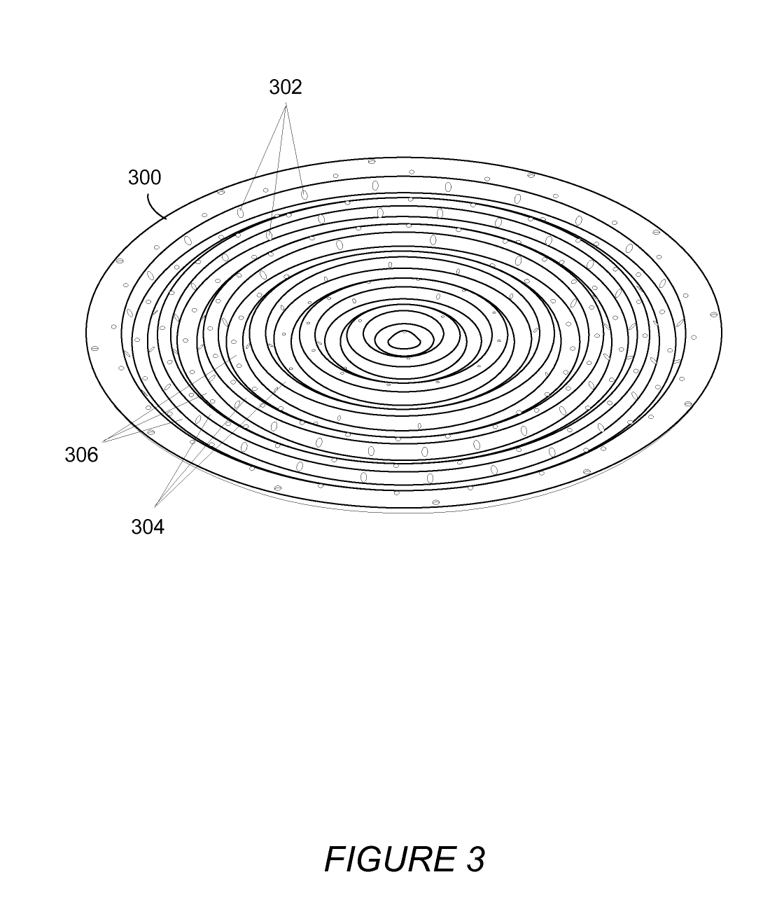

FIG. 3 depicts an embodiment of a showerhead 300. This showerhead may be used in devices including the downstream plasma device 100, the capacitively coupled plasma device 150, and similar devices. In some embodiments the showerhead 300 is fabricated out of an aluminum alloy. In some embodiments the aluminum alloy is anodized. As noted above, the showerhead is sputtered in some processes, and sputtering an aluminum alloy in the process chamber is not overly detrimental in some processes. In other embodiments the showerhead 300 is fabricated out of steel, alumina, or aluminum nitride. In some embodiments the surface of the showerhead facing the platen is coated with a coating. In further embodiments the coating is a coating of aluminum fluoride. As also noted above, the showerhead includes a plurality of holes or passageways though which a gas or a plasma species from the plasma may pass. A few of these holes are labeled 302. In some embodiments the showerhead 300 includes about 24,000 holes. The holes are small enough such that a plasma does not form within the hole, in some embodiments.

The showerhead 300 further includes a plurality of features configured to increase the surface of the showerhead relative to a flat surface. The plurality of features of the showerhead 300 include concentric ridges 304 and concentric valleys 306 with the center of the concentric ridges and concentric valleys at the center of the showerhead. In certain embodiments, the center of the concentric ridges and concentric valleys is on the showerhead but offset from the center of the showerhead. In further embodiments, the center of the concentric ridges and concentric valleys is not on the showerhead; i.e., the plurality of features of the showerhead include arcs. For the showerhead 300, the ridges and valleys have the same periodicity (i.e., the ridges and the valleys are configured as a periodic wave along a line drawn from the center of the showerhead to an edge). In other embodiments the ridges and valleys do not have the same periodicity. The showerhead 300 typically has a diameter slightly larger than the diameter of the platen. For example, when the platen is configured to support a 300 mm wafer, the showerhead 300 is about 320 mm in diameter; the amplitude of the periodic wave is about 0.5 inches, and the wavelength of the periodic wave is about 1 inch. The constant periodicity of the surface features may be useful in generating a uniform plasma in some embodiments, as discussed below.

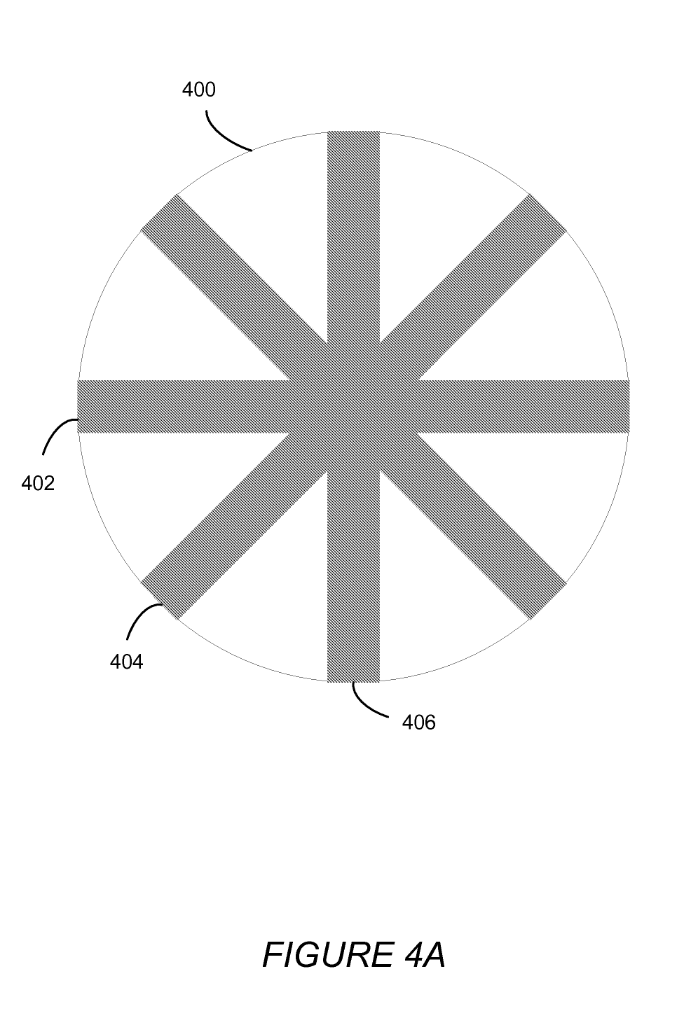

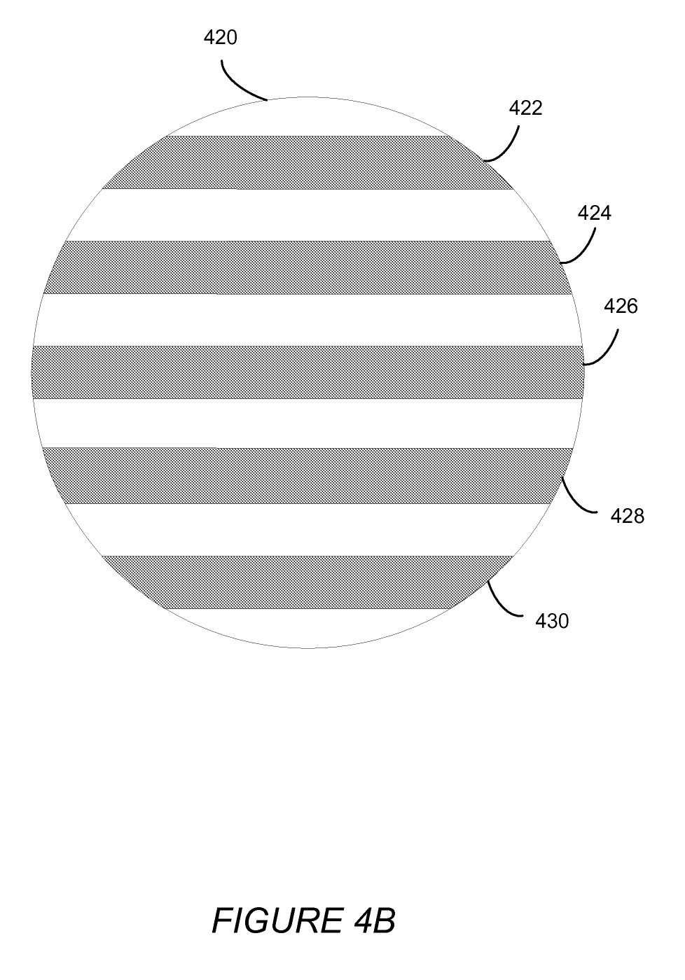

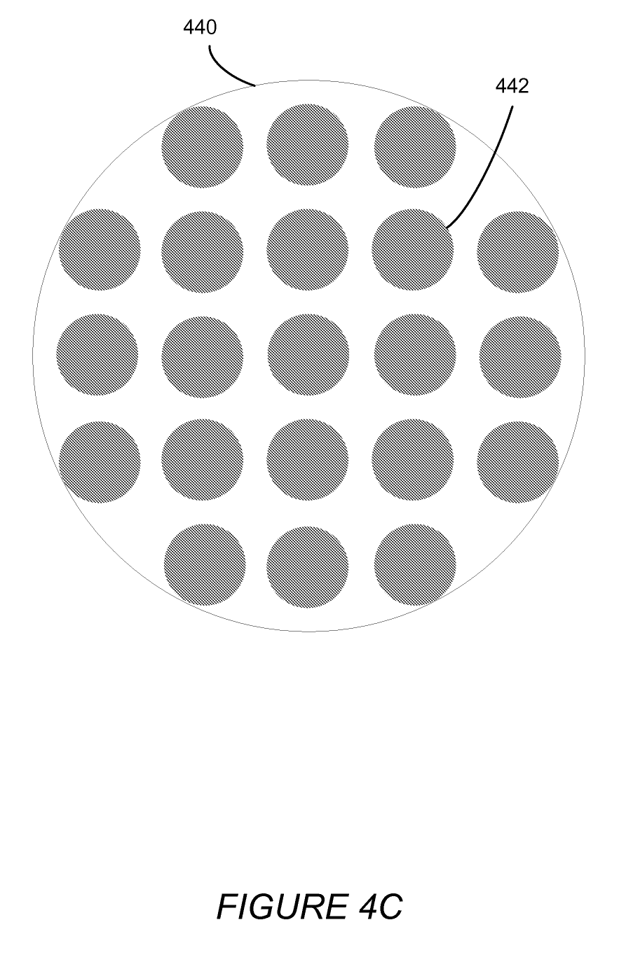

FIGS. 4A-4C depict further embodiments of showerheads that have an increased surface area that is achieved without increasing the diameter of the showerhead. The showerheads depicted in FIGS. 4A-4C have an increased surface area due to a plurality of features on the showerhead surface. In some embodiments the showerheads depicted in FIGS. 4A-4C are also fabricated out of an aluminum alloy. While not shown in FIGS. 4A-4C, embodiments of the depicted showerheads include a plurality of holes or passageways though which a gas or a plasma species from the plasma may pass.

FIG. 4A depicts another embodiment of a showerhead 400 with a plurality of features configured to increase the surface of the showerhead relative to a flat surface. In some embodiments the diameter of the showerhead 400 is about 320 mm. The showerhead 400 includes three ridges 402, 404, and 406 that pass though the center of the showerhead 400. In these embodiments, the three ridges may be about 1 inch wide and extend about 0.4 inches from the other regions of the surface of the showerhead.

FIG. 4B depicts another embodiment of a showerhead with a plurality of features configured to increase the surface area of the showerhead relative to a flat surface. In some embodiments the diameter of the showerhead 420 is about 320 mm. The showerhead 420 includes five ridges 422, 424, 426, 428, and 430 that pass across the showerhead 420. There are valleys between the ridges. For the showerhead 420, the ridges and valleys have the same periodicity (i.e., the ridges and the valleys are configured as a periodic wave along a line drawn from the top edge of the showerhead to the bottom edge of the showerhead and passing though the center of the showerhead; note that “top” and “bottom” edge are used to describe the showerhead in the orientation depicted in FIG. 4B, and because the showerhead is mounted in a horizontal plane in some embodiments of a plasma device, the “top” and “bottom” edges depend on the perspective of one viewing the showerhead). In other embodiments the ridges and valleys do not have the same periodicity. The showerhead 420 has a diameter of about 320 mm; the amplitude of the periodic wave is about 0.4 inches, and the wavelength of the periodic wave is about 1 inch. The constant periodicity of the surface features may be useful for generating a uniform plasma in some embodiments.

FIG. 4C depicts another embodiment of a showerhead with a plurality of features configured to increase the surface of the showerhead relative to a flat surface. In some embodiments the diameter of the showerhead 440 is about 320 mm. The plurality of features of the showerhead 440 include a plurality of periodically arrayed circular features or spots. One of the circular features is circular feature 442. The circular features are about 1 inch in diameter and extend about 0.4 inches from the other regions of the surface of the showerhead. The constant periodicity of the surface features may be useful for generating a uniform plasma in some embodiments.

While the embodiments described herein identify a showerhead or grounded electrode with a diameter of about 320 mm, the actual dimensions of the showerhead will vary to a large degree depending on the size of the platen configured to support the work piece. The platen is generally the same size as the work piece it supports, and the showerhead is generally slightly larger than the platen. The 320 mm showerheads described herein are configured to process 300 mm wafers. Over the years, however, wafer size has steadily increased and is expected to continue to increase in the future. With larger wafers, larger platens will be needed to support the wafers and in turn larger showerheads will be required.

Any configuration of features that increase the surface area of the showerhead may be used. For example, in certain embodiments, the plurality of features of the showerhead include a spiral. In some embodiments the center of the spiral is at the center of the showerhead, and in other embodiments the center of the spiral is on the showerhead but offset from the center of the showerhead. In further embodiments, the center of the spiral is not on the showerhead; i.e., the plurality of features of the showerhead include curves of the spiral. In certain embodiments the configuration of features that increase the surface area of the showerhead is subject to the limitations discussed below (i.e., the plasma sheath penetrating a feature of sufficient geometry and dimensions to support a high intensity plasma within the feature known as a hollow cathode discharge). In other embodiments the plurality of features include features that are not periodically arrayed and/or randomly arranged. Features may include valleys, ridges, spots, bumps, and any combination of these features in periodic or non-periodic and/or random arrangements. The features are spaced about 0.5 to 3.0 inches apart from one another in some embodiments. The features extend and/or protrude from the surface of the showerhead about 0.1 to 0.8 inches in some embodiments. Further, features may be symmetric or non-symmetric about the center of the showerhead. The showerhead may be a circular, square, hexagonal, or other shape appropriate for the work piece supported on the platen.

As noted above, any configuration of features that increases the surface area of the showerhead relative to a flat surface may be used. In certain embodiments, however, the features are spaced such that the plasma sheath of the plasma follows the surfaces of the features. The plasma sheath is a layer in a plasma that has a greater density of positive ions, and hence an overall excess positive charge, and that balances an opposite negative charge on the surface of a material with which it is in contact (e.g., the showerhead and the surface of the wafer). The thickness of the plasma sheath depends on various characteristics of plasma, discussed further below. Without the plasma sheath following the surfaces of the features on the showerhead, the advantages of the showerheads described herein may not be realized. Further, if the features are spaced closely to one another and/or have a high periodicity, the plasma may not follow the surfaces of the features and the plurality of features will effectively exhibit the surface area of a flat surface with respect to Equation 1. For example, if the plasma sheath thickness is large, the plasma sheath will not follow the surface of features of the showerhead if the features are too small. In general, as the feature size is reduced and becomes a small fraction of the sheath thickness, the effect of the plurality of features on a showerhead does not result in an increase in the ion energy.

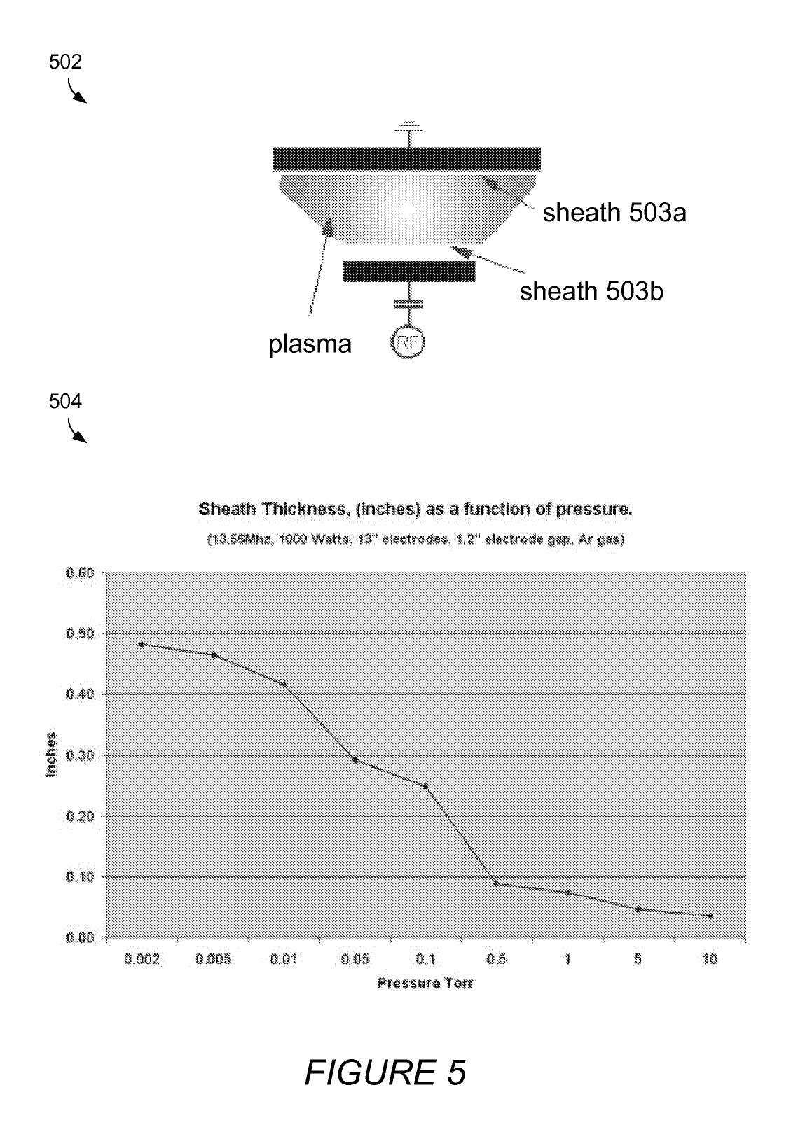

The plasma sheath thickness, which in part determines whether the plasma sheath will follow the surfaces of the features on the showerhead, is a function of the plasma and electron densities and temperatures; the plasma and electron densities and temperatures are dependent on the RF power levels, excitation frequency, pressures, gas types, and electrode dimensions used to generate the plasma. FIG. 5 includes a schematic diagram 502 of a capacitively coupled plasma device including a plasma with plasma sheaths 503a and 503b and a graph 504 showing the calculated thickness of the sheath versus pressure in a chamber for a set of operating conditions. The sheath thickness was calculated using plasma model which incorporates an expected operating pressure range of about 1 mtorr to 10 torr. Further parameters specified for this model include a RF power of 1000 Watts at 13.56 MHz, 13 inch grounded and powered electrodes, a 1.2 inch gap between the electrodes, and argon gas. As shown in FIG. 5, these calculations show a predicted sheath thickness in the range from about a few thousandths of an inch to a half of an inch depending on the pressure. According to the graph 504, finer and more closely spaced features could be used for the plurality of features on the surface of the showerhead when using higher operating pressures; due to the thinner plasma sheath at higher operating pressures, the plasma sheath would be capable of following finer and more closely spaced features. However, at higher operating pressures, the plasma sheath penetrating a feature of sufficient geometry and dimensions to support a hollow cathode discharge may be more likely to occur. These factors must be accounted for when configuring a showerhead with a plurality of features.

Increasing the surface area of the showerhead with any one of the configurations depicted in FIG. 3 and FIGS. 4A-4C increases the bias, resulting in an increased ion energy. For example, for the plasma generated with HF RF power shown in FIG. 2, the curve would shift to the right (i.e., higher ion energy) when using one of these showerheads in a plasma chamber.

The ability to increase the ion energy by changing the area of the showerhead in the manner described above allows plasma processes to be used in a number of different integrated circuit manufacturing operations. For example, the activation energy required by a process for a reaction to occur between ions impinging on the wafer surface and a material on a wafer surface may be supplied by thermal energy (i.e., by heating the wafer) or the kinetic energy of the impinging ions. In fabrication processes where it is not possible to heat the wafer (e.g., due to the thermal budget for the process being low), some or all of the activation energy may be provided by the kinetic energy of the ions. This may be made possible due to the ability to control the ion energy.

The ability to control the ion energy in this manner also allows for the use of plasma processes for stripping/removing materials from surfaces in the back-end processing of integrated circuits, especially in processes with low thermal budgets. Back-end processing includes the final assembly and packaging of an integrated circuit. Polymeric materials may be removed from trenches (about 100 microns by 100 microns, in some instances) with ions with a tailored ion energy that do not damage the almost completely fabricated integrated circuit. For example, these polymeric materials may need to be removed so that solder may be deposited in the trenches. In some instances, the polymeric materials include polyimide.

As noted above, in some embodiments of a plasma processing device, the surface of the showerhead facing the platen is about 0.5 to 2 inches from the surface of a wafer on the platen. In further embodiments the surface of the showerhead facing the platen is about 1.2 inches from the surface of a wafer on the platen. In yet further embodiments the surface of the showerhead facing the platen is about 0.1 to 0.9 inches from the surface of a wafer on the platen. In some embodiments the spacing is large enough so that the wafer is not exposed to non-uniformities that may be present in the plasma.

As explained above, one advantage of the showerhead with a plurality of features configured to increase the surface area of the showerhead relative to a flat surface includes an increased ion energy of the plasma without increasing the diameter of the showerhead and the components associated with the showerhead. Another advantage of such showerheads is that the showerheads increase the efficiency of the system by achieving higher ion energies with a lower RF power, resulting in potential energy savings by reducing the RF power needed to run some plasma processes. Further advantages of such showerheads include: an increase in the energy efficiency of the system by creating a more confined plasma; potential reduction of device cost by reducing the size of the process chamber; and a reduced sputtering of the showerhead due to an increase in the ion energy at the powered electrode and a decrease in ion energies at the showerhead.

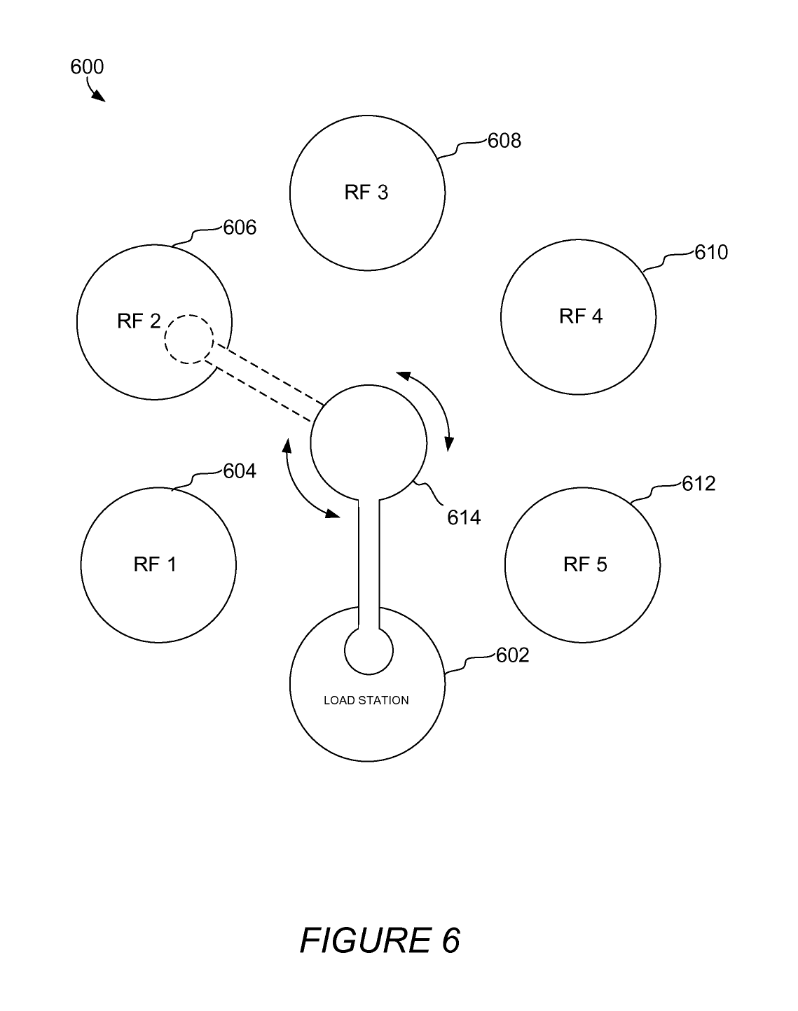

In some integrated circuit manufacturing tools, the tool has multiple wafer processing stations so that multiple wafers may be processed simultaneously. FIG. 6 is a simple block diagram showing a top-down view of a multi-station wafer strip unit tool 600. The strip unit tool 600 has five strip stations 604, 606, 608, 610 and 612 and one load station 602. Each strip station includes various components of the device 100 or the device 150, described above. Strip unit tool 600 is configured such that each strip station is capable of processing one wafer. All stations may be exposed to a common vacuum. Each of strip stations 604, 606, 608, 610, and 612 has its own RF power supply. Load station 602 is typically equipped with a load-lock station to allow the input of wafers into strip unit tool 600 without a break in vacuum. Load station 602 may also be equipped with a heat lamp to pre-heat wafers before transferring to a strip station. Strip station 612 is typically equipped with a load-lock station to allow the output of wafers from strip unit tool 600 without a break in vacuum. A robotic arm 614 transfers wafers from station to station.

During a typical manufacturing process, wafers are processed in batch mode. Batch mode processing can increase wafer though-put and commonly used in manufacturing operation. In batch mode, each wafer is transferred to, and processed in, each of the stations 602, 604, 606, 608, 610 and 612. For example, a typical batch mode process will proceed as follows: A wafer is first loaded into load station 602 where it is preheated with a heat lamp. Next, robotic arm 614 transfers the wafer to strip station 604 where it is plasma processed with a plasma for a time period sufficient to strip off about ⅕ of the photoresist. Robotic arm 614 then transfers the wafer to strip station 606 where it is processed with a plasma for a time period sufficient to strip off about another ⅕ of the remaining photoresist. This sequence is continued such that the wafer is processed at strip stations 608, 610, and 612. At strip station 612, the photoresist should be largely removed and the wafer is then unloaded from the strip unit tool 600.

The disclosed apparatus and devices may also be implemented in systems including lithography and/or patterning hardware for semiconductor fabrication. Further, the disclosed methods may be implemented in a process with lithography and/or patterning processes preceding or following the disclosed methods.

### Method

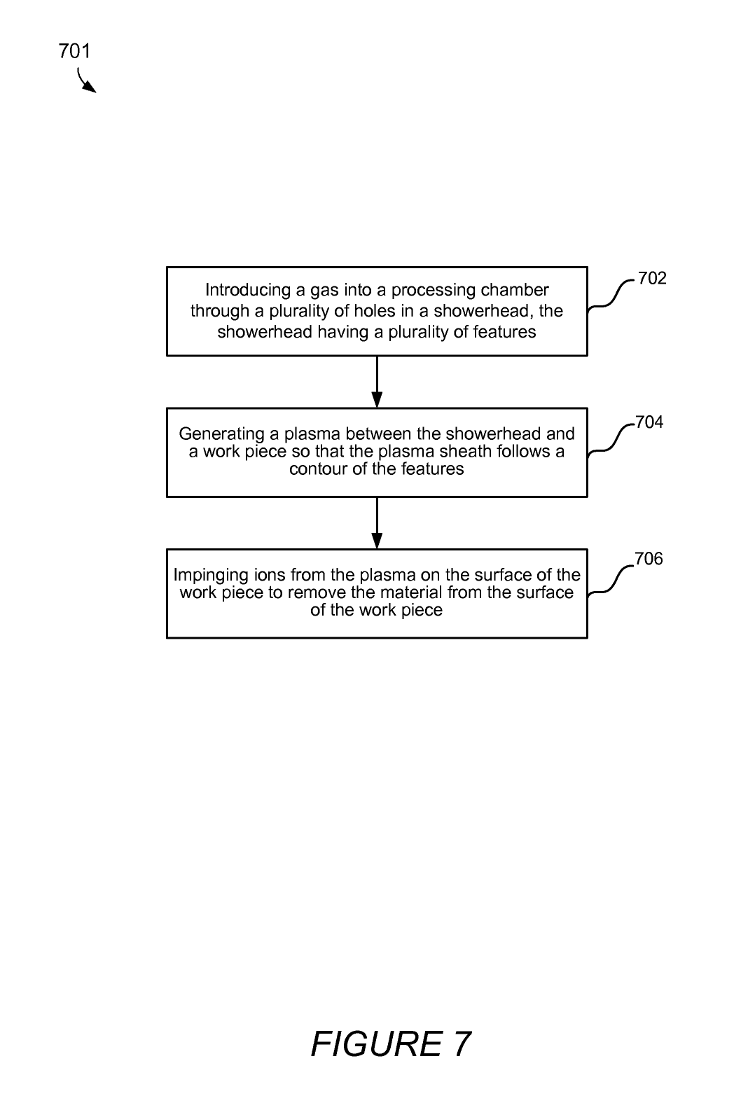

FIG. 7 depicts a process flow diagram according to certain embodiments. FIG. 7 depicts a method 701 for removing a material from a surface of a work piece. In certain embodiments the material that is removed includes a photoresist, with the photoresist overlaying a low-K dielectric on a wafer. In other embodiments the material that is removed includes a polyimide. The embodiments of method 701 may be performed with the apparatus and devices described above.

In operation 702, a gas is introduced into a processing chamber through a plurality of holes in a showerhead. In embodiments in which the material is to be removed with a physical sputtering mechanism, the gas includes an inert gas such as argon. In embodiments in which the material is to be removed with an oxidation process, the gas includes oxygen or an oxygen containing species. In further embodiments the gas includes radicals generated from an inductively coupled plasma. For instance, in some embodiments, the radicals include oxygen radicals. Other process gasses may also be used, including hydrogen, ammonia, carbon tetrafluoride, and nitrogen.

In operation 704, a plasma is generated between the showerhead and a work piece support. The work piece support is configured to support the work piece. The surface of the showerhead facing the work piece support includes a plurality of features configured such that a plasma sheath of the plasma follows a contour of the features. The plasma sheath following the contour of the features in the showerhead increases the effective surface area of the showerhead in further embodiments. The plurality of features is also configured to prevent arcing in the plasma between features in some embodiments. In certain embodiments the plasma is generated by applying a RF power to the work piece support. The RF power may include a high-frequency power of about 13.56 mega-Hertz, a low-frequency power of about 400 kilo-Hertz, or both a high-frequency power and a low-frequency power.

In operation 706, the ions from the plasma impinge on the surface of the work piece to remove the material from the surface of the work piece. As noted above, the material may be removed by a sputtering process or the material may be removed by an oxidation or other chemical process. In certain embodiments the work piece is at a temperature of about 20 to 25° C. when the ions impinge the surface of the work piece. Using a showerhead that includes a plurality of features configured such that a plasma sheath of the plasma follows a contour of the features serves to increase the surface area of the showerhead and increases the ion energy. Increasing the ion energy in this manner allows material to be removed from a work piece by oxidizing the material without heating the work piece; the activation energy needed to oxidize the material is provided by the kinetic energy of the ions and not thermal energy generated by heating the work piece.

In another embodiment of a method for removing a material from a surface of a work piece, a plasma is generated from a gaseous species in a processing chamber. The processing chamber includes a work piece support with the work piece support configured to support the work piece. The processing chamber also includes a showerhead, the showerhead including a plurality of holes configured to allow gaseous species to pass into a region between the work piece support and the showerhead. A surface of the showerhead facing the work piece support includes a plurality of features configured to increase the surface area of the showerhead relative to a flat surface. Ions from the plasma impinge on the surface of the work piece to remove the material from the surface of the work piece.

### Experimental Results

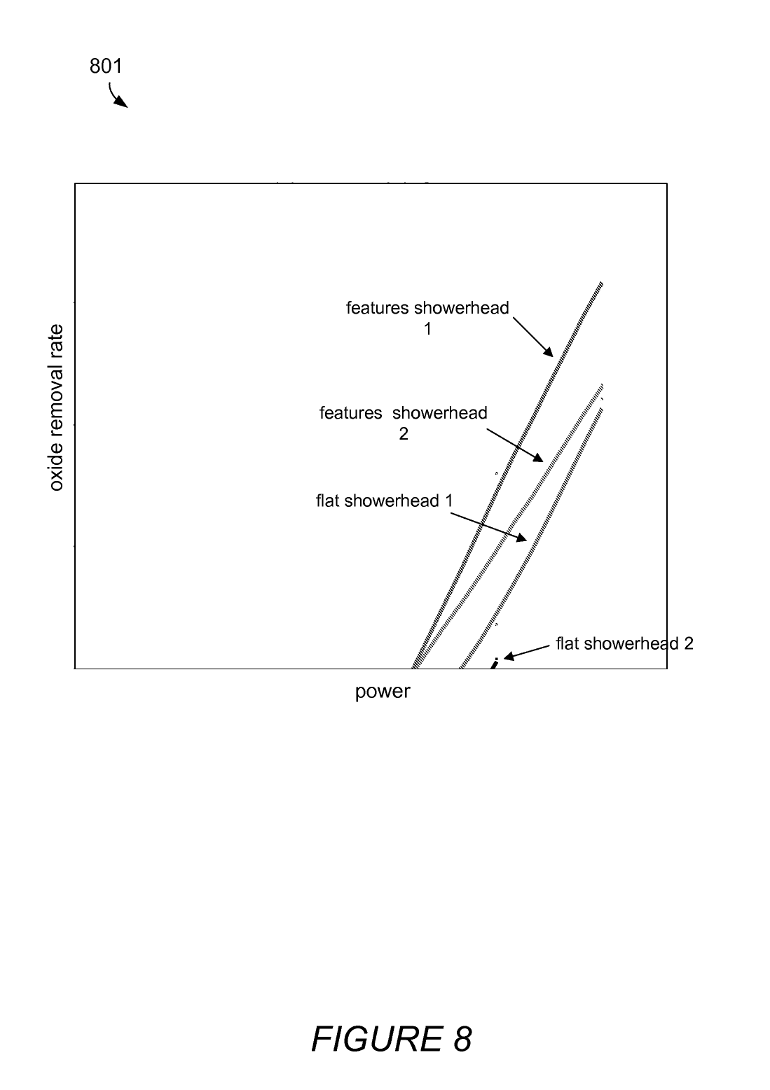

Experiments were performed to demonstrate the advantages of a showerhead having a plurality of features configured to increase the surface of the showerhead relative to a flat surface. FIG. 8 is a graph showing thermal oxide removal rate versus the plasma power using a capacitively coupled device outfitted with different showerheads. A thermal oxide on a work piece was sputtered with argon at different power levels with the different showerheads. Thermal oxide is sputtered with argon ions when argon ions generated in the plasma have an energy of 27 eV. Thus, by increasing the plasma power and determining when sputtering of the thermal oxide begins, the power level at which the ion energy is 27 eV can be determined.

As shown in FIG. 8, for the showerheads with a plurality of features (features showerhead 1 and features showerhead 2) the ion energy is higher (i.e., at least 27 eV, the ion energy at which the thermal oxide begins to be sputtered) at lower plasma powers compared to the flat showerheads (flat showerhead 1 and flat showerhead 2). Features showerhead 1 and features showerhead 2 are two showerheads configured similar to the showerhead 300 depicted in FIG. 3. Features showerhead 1 is an un-anodized aluminum alloy showerhead with the plurality of features (similar to the plurality of features of showerhead 300) having a wavelength of 1 inch and an amplitude of 0.437 inches. Features showerhead 2 is an un-anodized aluminum alloy showerhead with the plurality of features (similar to the plurality of features of showerhead 300) having a wavelength of 1 inch and an amplitude of 0.317 inches. Flat showerhead 1 is a flat anodized aluminum alloy showerhead. Flat showerhead 2 is a flat un-anodized aluminum alloy showerhead.

Although various details have been omitted for clarity's sake, various design alternatives may be implemented. Therefore, the present examples are to be considered as illustrative and not restrictive, and the invention is not to be limited to the details given herein, but may be modified within the scope of the appended claims.

1. A plasma processing device, comprising:
a work piece support, the work piece support configured to support a work piece; and
a showerhead, the showerhead including a plurality of holes configured to allow gaseous species to pass into a region between the work piece support and the showerhead, a surface of the showerhead facing the work piece support including a plurality of features configured to increase the surface area of the showerhead relative to a flat surface.

2. The device of claim 1, wherein the plurality of features includes concentric ridges and concentric valleys.

3. The device of claim 1, wherein the plurality of features includes ridges and valleys radiating from a center of the showerhead.

4. The device of claim 1, wherein the plurality of features includes ridges and valleys running across the showerhead.

5. The device of claim 1, wherein the plurality of features includes a plurality of periodically arrayed features.

6. The device of claim 1, wherein the plurality of features includes a plurality of randomly patterned features.

7. The device of claim 1, further comprising:
an RF power source configured to apply radio frequency power to the work piece support.

8. The device of claim 7, wherein the radio frequency power source includes a low frequency power source.

9. The device of claim 7, wherein the radio frequency power source includes a high frequency power source.

10. The device of claim 1, wherein the plurality of holes in the showerhead includes about 24,000 holes.

11. The device of claim 1, wherein the showerhead comprises an aluminum alloy.

12. The device of claim 1, wherein the distance between the surface of the showerhead and the work piece support is about 0.1 to 0.9 inches.

13. The device of claim 1, wherein the distance between the surface of the showerhead and the work piece support is about 1.2 inches.

14. The device of claim 1, further comprising:
a plasma source chamber, the plasma source chamber located upstream from the showerhead, wherein the gaseous species allowed to pass through the showerhead includes radicals from the plasma source chamber.

15. An apparatus configured for semiconductor lithography, comprising:
a device configured for photoresist application;
a device configured for photoresist exposure; and
the device of claim 1, wherein the device is configured for photoresist removal.

16. A showerhead configured to use in a plasma processing device, the showerhead comprising:
a plurality of holes configured to allow gaseous species to pass; and
a surface configured to face a work piece, the surface including a plurality of features configured to increase the surface area of the showerhead relative to a flat surface.

17. The showerhead of claim 16, wherein the plurality of features includes concentric ridges and concentric valleys.

18. The showerhead of claim 16, wherein the plurality of features includes ridges and valleys radiating from a center of the showerhead.

19. The showerhead of claim 16, wherein the plurality of features includes ridges and valleys running across the showerhead.

20. The showerhead of claim 16, wherein the plurality of features includes a plurality of periodically arrayed features.

21. The showerhead of claim 16, wherein the plurality of features includes a plurality of randomly patterned features.

22. The showerhead of claim 16, wherein the plurality of holes in the showerhead includes about 24,000 holes.

23. The showerhead of claim 16, wherein the showerhead comprises an aluminum alloy.

24. The showerhead of claim 16, wherein the plurality of features includes a spiral.

25. A method, comprising:
introducing a gas into a processing chamber through a plurality of holes in a showerhead;
generating a plasma between the showerhead and a work piece support, a surface of the showerhead facing the work piece support including a plurality of features configured such that a plasma sheath of the plasma follows a contour of the features, the work piece support configured to support a work piece; and
impinging ions from the plasma on a surface of the work piece to remove a material from the surface of the work piece.

26-39. (canceled)
